(19) United States
(12) Patent Application Publication
(10) Pub. No.: US 2025/0164558 A1
(43) Pub. Date: May 22, 2025

(54) ABNORMALITY DETECTION DEVICE AND ABNORMALITY DETECTION METHOD

(71) Applicant: OMRON Corporation, Kyoto-shi, Kyoto (JP)

(72) Inventors: Takenori HATSUDA, Kyoto-shi, KYOTO (JP); Takashi KAKIUCHI, Kyoto-shi, KYOTO (JP); Takuya YAMAZAKI, Kyoto-shi, KYOTO (JP)

(21) Appl. No.: 18/841,531

(22) PCT Filed: Jan. 24, 2023
(86) PCT No.: PCT/JP2023/001996

§ 371 Date: Aug. 26, 2024

(30) Foreign Application Priority Data
Mar. 7, 2022 (JP) 2022-034825

(51) Int. Cl. G01R 31/327

(52) U.S. Cl. CPC G01R 31/3278

(57) ABSTRACT

An abnormality detection device includes: an acquisition unit configured to acquire a state of a relay that is connected to an instrument to be monitored and controls opening and closing of a circuit to which the instrument is connected; a detector configured to detect an abnormality of the instrument on the basis of the state of the relay or a change in the state of the relay; and a notifying unit configured to notify a user of the abnormality detected by the detector.

### TECHNICAL FIELD

The present invention relates to an abnormality detection device and an abnormality detection method.

### BACKGROUND ART

It is important to detect an abnormality or deterioration of an instrument or predict a failure thereof in order to improve an operation rate of a system. Various instruments can control opening/closing or the like of an electric circuit by being connected to a relay. Patent Document 1 discloses a technique of detecting a load current supplied to a motor (instrument) to be monitored connected to a multi-relay, and determining whether or not there is a sign of occurrence of an abnormality on the basis of a detection result of a load current and a detection result of the presence or absence of the occurrence of the abnormality.

### CITATION LIST

### Patent Literature

Patent Document 1: Japanese Unexamined Patent Publication No. 2018-207589

### SUMMARY OF THE INVENTION

### Problems to be Solved by the Invention

A sensor or the like for detecting a load current or the like of a motor is directly attached to the motor to be monitored, and new wiring to a control circuit is installed. In a case where a sensor or the like is directly attached to a motor to be monitored in order to detect a failure of the motor, there is a possibility that cost increases and labor is required. In addition, in some cases, it is difficult to retrofit an existing motor with a sensor or the like because it is difficult to refurbish an existing facility or it is difficult to physically install the motor. In a case where an abnormality is detected by detecting a load current on the motor side, the detection result of the load current is transferred to a monitoring server connected to the relay side, which causes the processing load to increase.

In one aspect, an object of the present invention is to provide a technique of detecting an abnormality of an instrument connected to a relay without using information acquired from the instrument side and indirectly predicting a failure of the instrument.

### Means for Solving the Problem

In order to achieve the above object, the present invention employs the following configurations.

A first aspect of the present disclosure is an abnormality detection device including: an acquisition unit configured to acquire a state of a relay that is connected to an instrument to be monitored and controls opening and closing of a circuit to which the instrument is connected; a detector configured to detect an abnormality of the instrument on the basis of the state of the relay or a change in the state of the relay; and a notifying unit configured to notify a user of the abnormality detected by the detector. The abnormality detection device can acquire the state of the relay and predict or detect an abnormality of the instrument without using information acquired from the device side. A monitoring sensor or the like does not need to be attached to the instrument to be monitored, and the abnormality detection device can indirectly monitor the instrument in a state of being separated from the circuit on the instrument side.

The detector may detect an abnormality of the instrument by inputting the state of the relay or a change in the state of the relay acquired by the acquisition unit to a detection model, the detection model being subjected to machine learning using the state of the relay or the change in the state of the relay as input data and using an abnormality of the instrument related to the state of the relay or the change in the state of the relay as output data. By inferring an abnormality of the instrument from the state of the relay or the change in the state of the relay using the learned model by machine learning, the abnormality detection device can accurately predict or detect the abnormality of the device.

The detection model may be a learned model obtained by performing machine learning using, as input data, a change amount of an index indicating a wear amount of a contact of the relay per unit time or per predetermined number of opening and closing times. In a case where the change amount in the index per unit time or per predetermined number of opening and closing times increases, that is, in a case where the wear of the contact of the relay rapidly progresses, the abnormality detection device can predict or detect an abnormality of the instrument.

The detection model may be a learned model obtained by performing machine learning using, as input data, time series data indicating a change in an index indicating a wear amount of a contact of the relay for the number of opening and closing times or a use time of the contact of the relay. In a case where a change in the index is measured, the change being different from a change in the index in a case where the instrument is normally operating, the abnormality detection device can predict or detect an abnormality of the instrument.

The detection model may be a learned model obtained by further performing machine learning using, as the output data, a period until a failure occurs in the instrument. The abnormality detection device can infer a period until a failure occurs in the instrument on the basis of the present state of the relay or a change in the state of the relay up to the present time. With this configuration, the user can take an appropriate measure before the failure occurs in the instrument.

The detection model may be a learned model obtained by performing machine learning using an abnormality of the relay as the output data. For example, the abnormality detection device can detect an abnormality such as a failure or deterioration of the relay from a current waveform flowing through a coil at the time when the contact of the relay is opened and closed. Because the abnormality of the relay is caused by an abnormality of the instrument in some cases, the abnormality detection device can predict or detect the abnormality of the instrument by detecting the abnormality of the relay itself.

The state of the relay may include at least one of information indicating a wear amount of a contact of the relay, information indicating a distance between a coil and an iron piece at the time when the contact of the relay is closed, a current waveform of an electric current flowing through the coil at the time when the contact of the relay is opened, and a voltage waveform of a voltage applied to the coil at the time when the contact of the relay is opened. The state of the relay only needs to be a state that changes due to an abnormality of the instrument, and can be information obtained by combining the wear amount of the contact of the relay, an index indicating the wear amount of the contact, the electric current flowing through the coil, the voltage related to the coil, and the like. The abnormality detection device can accurately predict or detect an abnormality of the instrument on the basis of various types of information regarding the state of the relay.

The detector may detect an abnormality of the relay on the basis of the state of the relay or a change in the state of the relay. The abnormality detection device can detect an abnormality of the relay itself on the basis of a state of the relay such as a current waveform of an electric current flowing through the coil at the time when the contact of the relay is opened or a voltage waveform of a voltage applied to the coil at the time when the contact of the relay is opened.

A second aspect of the present invention is an abnormality detection method including:
an acquisition step of causing a computer to acquire a state of a relay that is connected to an instrument to be monitored and controls opening and closing of a circuit to which the instrument is connected;
a detection step of causing the computer to detect an abnormality of the instrument on the basis of the state of the relay or a change in the state of the relay; and
a notification step of causing the computer to notify a user of the abnormality detected in the detection step.

Furthermore, the present invention can also be regarded as a program implementing such a method or a recording medium in which such a program is non-transiently recorded. Note that each of the above methods and processing can be combined with each other as much as possible to constitute the present invention.

### Effect of the Invention

According to the present invention, it is possible to detect an abnormality of an instrument connected to a relay without using information acquired from the instrument side and to indirectly predict a failure of the instrument.

### BRIEF DESCRIPTION OF THE DRAWINGS

FIG. 1 is a diagram exemplifying a configuration of an abnormality detection device.

FIG. 2 is a diagram for explaining a mechanism of a relay.

FIG. 3 is a diagram for explaining abnormality detection of an instrument based on a change in an AF amount.

FIG. 4 is a diagram for explaining estimation of the AF amount.

FIGS. 5A and 5B are diagrams exemplifying a waveform of a coil current at the time when a contact is opened.

### MODE FOR CARRYING OUT THE INVENTION

Hereinafter, an embodiment according to an aspect of the present invention will be described with reference to the drawings.

### Application Example

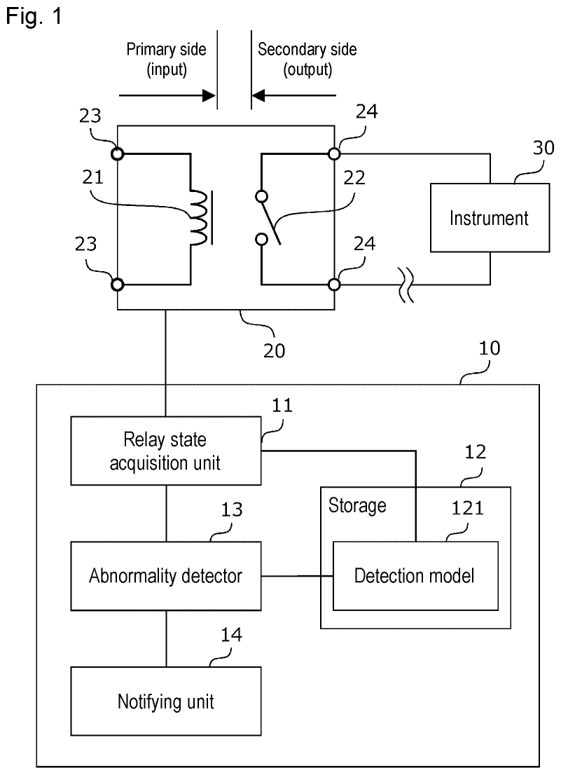

An application example of an abnormality detection device 10 will be described with reference to FIG. 1. The abnormality detection device indirectly predicts or detects a failure of an instrument 30 (including a motor or the like that drives the instrument) by monitoring a state of a relay 20 connected to the instrument 30.

The relay 20 includes a coil 21 on the primary side (input side). A not-illustrated switch is connected to an input-side terminal 23, and an electric current flows through the coil 21 by turning on the switch. When the electric current flows through the coil 21, electromagnetic force is generated. The generated electromagnetic force brings a contact 22 into a closed state, and the electric current flows through a secondary-side (output side) circuit separated from a primary-side circuit. The instrument 30 connected to an output-side terminal 24 is driven by the electric current flowing through the secondary-side circuit.

The primary-side circuit of the relay 20 includes a circuit for measuring an electric current flowing through the coil 21 and outputting a measurement result. The abnormality detection device 10 is connected to the primary-side circuit of the relay 20, and acquires a state of the relay 20 from the electric current or the like flowing through the coil 21. The state of the relay 20 includes, for example, information indicating a wear amount of the contact of the relay 20, information indicating a distance (an armature follow (AF) amount) between the coil and an iron piece at the time when the contact of the relay 20 is closed, and a current waveform of an electric current flowing through the coil at the time when the contact of the relay 20 is opened.

The abnormality detection device 10 can detect the abnormality of the instrument 30 by acquiring the state of the relay 20 or a change in the state of the relay 20 and comparing the acquired state with the state of the relay 20 or the change in the state of the relay 20 at the time when an abnormality of the instrument 30 is detected.

Further, the abnormality detection device 10 may detect an abnormality of the instrument 30 by using a detection model 121 configured to detect the abnormality of the instrument 30 connected to the relay 20. The detection model 121 is a learned model obtained by learning, by machine learning, teaching data having the state of the relay 20 as input data and an abnormality of the instrument 30 related to the state of the relay 20 or the change in the state of the relay 20 as output data. The abnormality detection device 10 can detect an abnormality of the instrument 30 by inputting the state of the relay 20 or a change in the state of the relay 20 that has been acquired to the detection model 121.

The detection model 121 is, for example, a model obtained by learning, as output data, an abnormal state such as a failure, deterioration, or operation stop of the instrument 30 connected to the relay 20 from the state of the relay 20 or a change in the state of the relay 20. Furthermore, the detection model 121 may be a model that can further learn, as output data, a period until a failure occurs in the instrument 30, and can also infer a prediction period until a failure occurs in the instrument 30 from a change in the state of the relay 20.

The detection model 121 may be a model obtained by learning an abnormality such as a failure or deterioration of the relay 20 itself as output data. The abnormality of the relay 20 is mainly caused by an abnormality of the instrument 30 connected to the relay 20. Therefore, the abnormality detection device 10 can predict or detect an abnormality of the instrument 30 on the basis of the abnormality of the relay 20.

The abnormality detection device 10 notifies a user of the detected abnormality of the instrument 30. With this configuration, the abnormality detection device 10 can predict or detect an abnormality of the instrument 30 by monitoring the state of the relay 20 or a change in the state of the relay 20.

As described above, the abnormality detection device 10 predicts or detects an abnormality of the instrument 30 by using not the information on the secondary side (the connected instrument 30 side) of the relay 20 but the information on the primary side. The abnormality detection device 10 can predict or detect the abnormality of the instrument 30 on the basis of the information acquired from the primary-side circuit in a state in which the circuit on the instrument 30 side through which the electric current larger than the electric current flowing through the coil 21 flows is disconnected when the contact 22 is closed. That is, the abnormality detection device 10 connected to the primary side can indirectly monitor the instrument 30 connected to the secondary side.

Furthermore, because the abnormality detection device 10 is connected to the primary-side circuit, the information on the relay 20 can be more easily acquired from the primary-side circuit than in a case of acquiring the information on the state of the instrument 30 from a sensor or the like attached to the instrument 30. The abnormality detection device 10 can monitor the instrument 30 at low cost by detecting an abnormality of the instrument 30 on the basis of the information acquired from the primary-side circuit.

Note that the abnormality detection device 10 cannot only detect an abnormality of the instrument 30 connected to the relay 20, but can also detect an abnormality of the relay 20 from the state of the relay 20 or a change in the state of the relay 20. The abnormality of the relay 20 is, for example, a failure of an armature (iron piece) occurring due to contact welding or a mechanical failure.

### Embodiment

### (Device Configuration)

A device configuration of the abnormality detection device 10 will be described with reference to FIG. 1. The abnormality detection device 10 includes a relay state acquisition unit 11, a storage 12, an abnormality detector 13, and a notifying unit 14.

The relay state acquisition unit 11 (corresponding to an acquisition unit) acquires information on the state of the relay from a circuit connected to the primary side of the relay 20. The state of the relay 20 only needs to be information indicating a state such as a failure or deterioration of the relay 20 occurring due to an abnormality of the instrument 30. The state of the relay 20 includes, for example, information indicating a wear amount of the contact of the relay 20, information indicating a distance (AF amount) between the coil and an iron piece at the time when the contact of the relay 20 is closed, and a current waveform of an electric current flowing through the coil at the time when the contact of the relay 20 is opened.

The storage 12 stores the information acquired by the relay state acquisition unit 11. In addition, the storage 12 stores the detection model 121. The detection model 121 is a learned model obtained by machine learning, as teaching data, the state of the relay 20 or a change in the state of the relay 20, an abnormality of the instrument 30 related to the state of the relay 20 or the change in the state of the relay 20, and the like.

The abnormality detector 13 (corresponding to a detector) detects an abnormality of the instrument 30 on the basis of the information acquired by the relay state acquisition unit 11. The abnormality detector 13 may input the information acquired by the relay state acquisition unit 11 to the detection model 121 to predict or detect an abnormality of the instrument 30. Note that the abnormality detector 13 is not limited to an abnormality of the instrument 30, but can also detect an abnormality of the relay 20 itself. Hereinafter, a case where an abnormality of the instrument 30 is detected will be described, but the present embodiment can also be applied within a possible range to a case where an abnormality of the relay 20 itself is detected.

The detection model 121 may be a model obtained by learning the state of the relay 20 or a change in the state of the relay 20 as input data, and an abnormal state such as a failure, deterioration, or the like of the instrument 30 as output data. In addition, the detection model 121 may be a model obtained by learning, as output data, a period until a failure occurs in the instrument 30. By using these detection models 121, the abnormality detector 13 can infer an abnormal state such as a failure or deterioration of the instrument 30, a predicted period until a failure of the instrument 30, or the like. The notifying unit 14 notifies the user of an abnormality of the instrument 30 predicted or detected by the abnormality detector 13. For example, the notifying unit 14 displays information on the abnormality of the instrument 30 on a display or the like included in the abnormality detection device 10. Furthermore, the notifying unit 14 may transmit information on the abnormality of the instrument 30 to the terminal or the like of the user to notify the user of the abnormality of the instrument 30.

Note that each functional unit in FIG. 1 may be or may not be individual hardware. The functions of two or more functional units may be implemented by common hardware. Each of the plurality of functions of one functional unit may be realized by individual hardware. Two or more functions of one functional unit may be implemented by common hardware. In addition, each functional unit may or may not be implemented by hardware. For example, the device may include a processor and a memory in which a control program is stored. Then, the functions of at least a part of the functional units included in the device may be implemented by the processor reading and executing the control program from the memory.

### (Mechanism of Relay)

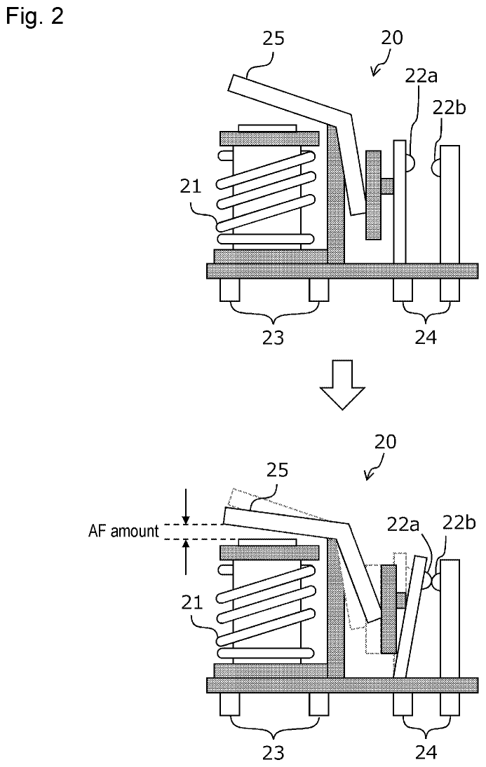

A mechanism of the relay 20 will be described with reference to FIG. 2. The relay 20 includes the coil 21, the contact 22, the input-side terminal 23, the output-side terminal 24, and an iron piece 25. The contact 22 includes a movable contact 22a and a fixed contact 22b. Note that the movable contact 22a and the fixed contact 22b are collectively referred to as the contact 22.

When the electric current flows through the coil 21 via the input-side terminal 23, the iron piece 25 is attracted toward the coil 21 by the generated electromagnetic force. By having the angle of the iron piece 25 changed, the movable contact 22a comes into contact with the fixed contact 22b, and the contact 22 is closed. The contact 22 is closed to cause the electric current to flow through the circuit on the side of the output-side terminal 24, and the instrument 30 connected to the output-side terminal 24 is driven.

As illustrated in FIG. 2, the AF amount is a distance between the coil and the iron piece 25 at the time when the contact 22 of the relay 20 is closed. The AF amount can be measured, for example, by analysis of an image captured by a camera, or can be measured by using a laser displacement meter. The AF amount can be an index indicating the wear amount of the contact 22 of the relay 20.

When the electric current does not flow through the coil 21 any longer, the electromagnetic force disappears, and the iron piece 25 is separated from the coil 21. By having the angle of the iron piece 25 returned to the original angle, the movable contact 22a is separated from the fixed contact 22b, and the contact 22 is opened.

Note that an example of detecting an abnormality of the instrument 30 on the basis of the state of the relay 20 illustrated in FIG. 2 will be described below, but the configuration of the relay 20 is not limited to the example illustrated in FIG. 2. The present embodiment is applicable to the relay 20 in which the state changes due to an abnormality of the instrument 30 and from which change in the state can be acquired.

### Example 1 of State of Relay

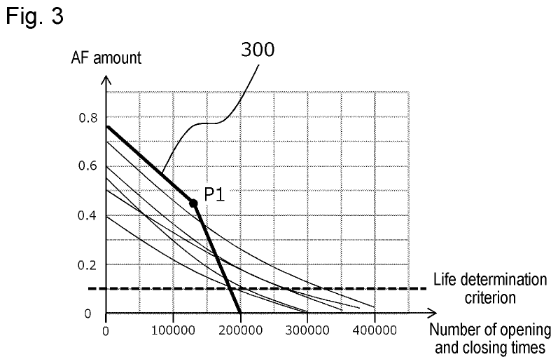

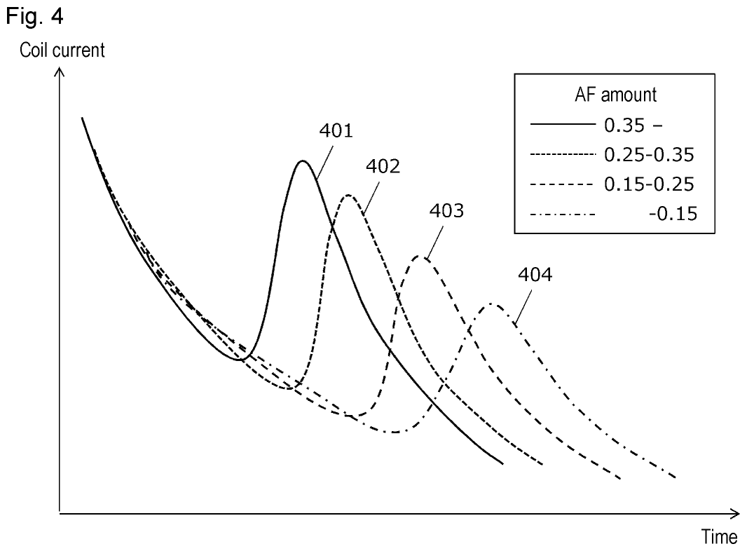

With reference to FIGS. 3 and 4, a case where information on the wear amount of the contact 22 and information on the AF amount are acquired as the state of the relay 20 will be described. As the contact 22 is repeatedly opened and closed, the movable contact 22a and the fixed contact 22b wear. The wear amount of the contact 22 correlates with the distance (AF amount) between the coil and the iron piece at the time when the contact 22 is closed. As the wear of the contact 22 progresses, the AF amount decreases. The AF amount can be used as an index for estimating the wear amount of the contact 22.

Detection of an abnormality of the instrument 30 based on a change in the AF amount will be described with reference to FIG. 3. In the graph illustrated in FIG. 3, the vertical axis represents the AF amount, and the horizontal axis represents the number of opening and closing times of the contact 22. In the following description, the horizontal axis represents the number of opening and closing times of the contact 22, but the horizontal axis may represent the use time of the contact 22.

In FIG. 3, the AF amount at the start of use differs for each relay 20 due to variations in manufacturing, but the AF amount of each relay 20 decreases as the number of opening and closing times of the contact 22 increases. That is, the wear amount of the contact 22 of each relay 20 increases as the number of opening and closing times of the contact 22 increases.

In a case where there is no abnormality or the like in the instrument 30, the AF amount decreases substantially linearly, and when the AF amount decreases to a value of a life determination criterion (0.1 in the example of FIG. 3), it is determined that the contact 22 has reached the end of the life and the contact 22 is replaced. However, for the relay 20 indicated by a graph 300, a decrease amount of the AF amount per predetermined number of opening and closing times is increased after a point P1 as compared with before the point P1. The significant decrease in the AF amount is considered to be caused by a load applied to the circuit due to a failure or the like of the instrument 30 connected to the relay 20.

Therefore, the abnormality detector 13 can predict or detect an abnormality of the instrument 30 by monitoring a change in the AF amount. The abnormality detector 13 can predict that an abnormality of the instrument 30 has occurred in a case where the decrease amount of the AF amount per predetermined number of opening and closing times changes or becomes equal to or greater than a threshold.

The abnormality detector 13 may predict or detect an abnormality of the instrument 30 by using the detection model 121 obtained by learning, as input data, the number of opening and closing times of the contact 22 and the AF amount. In a case where the AF amount is smaller than that at the normal time of the instrument 30 for the number of opening and closing times, the abnormality detector 13 can detect the abnormality of the instrument 30 by inputting the number of opening and closing times of the contact 22 and the AF amount to the detection model 121.

Furthermore, the detection model 121 may be a model obtained by learning, as input data, a change amount of the AF amount per unit time or per predetermined number of opening and closing times. The predetermined number of opening and closing times can be, for example, between 10 times to 100 times. As illustrated in the graph 300, in a case where the change amount of the AF amount increases after the point P1 as compared with before the point P1, the abnormality detector 13 can detect an abnormality of the instrument 30 by inputting the change amount of the AF amount per unit time or per predetermined number of opening and closing times to the detection model 121.

Furthermore, the detection model 121 may be a model obtained by learning, as input data, time-series data indicating a change in the AF amount for the number of opening and closing times or the use time of the contact 22. By inputting the time-series data including the point P1 of the graph 300 to the detection model 121, the abnormality detector 13 can detect an abnormality of the instrument 30.

Here, estimation of the AF amount will be described with reference to FIG. 4. The AF amount can be estimated from the current waveform flowing through the coil 21. The graph of the current waveform illustrated in FIG. 4 illustrates a change in the electric current (hereinafter, also referred to as a coil current.) flowing through the coil 21 when the switch for flowing the current to the coil 21 is turned off and the movable contact 22a returns to the original position. In the graph illustrated in FIG. 4, the vertical axis represents the coil current, and the horizontal axis represents time.

When the switch for flowing the electric current to the coil 21 is turned off, the coil current decreases. When the coil current decreases, the iron piece 25 is separated from the coil 21, and the contact 22 is opened. At the time when the iron piece 25 is separated from the coil 21, a phenomenon that the coil current once rises and then decreases occurs. As the wear of the contact 22 progresses and the AF amount decreases, the time from when the switch is turned off until the contact 22 is opened becomes longer. Therefore, the AF amount can be estimated from the current waveform of the coil current at the time when the movable contact 22a returns to the original position and the contact 22 is opened.

In FIG. 4, a graph 401 illustrates a change in the coil current in a case where the AF amount is 0.35 or more. A graph 402 illustrates a change in the coil current in a case where the AF amount is 0.25 or more and less than 0.35. A graph 403 illustrates a change in the coil current in a case where the AF amount is 0.15 or more and less than 0.25. A graph 404 illustrates a change in the coil current in a case where the AF amount is less than 0.15. As described above, as the AF amount decreases, the time until the movable contact 22a returns to the original position becomes longer.

By estimating the AF amount from the current waveform of the coil current and by using the detection model 121 obtained by learning, as input data, the estimated AF amount and the number of opening and closing times of the contact 22 at the time of estimation, the abnormality detector 13 can predict or detect the abnormality of the instrument 30.

Further, the detection model 121 may be a model obtained by learning, as input data, a change of the AF amount per unit time or per predetermined number of opening and closing times. Still further, the detection model 121 may be a model obtained by learning, as input data, time-series data indicating a change in the estimated AF amount.

### Example 2 of State of Relay

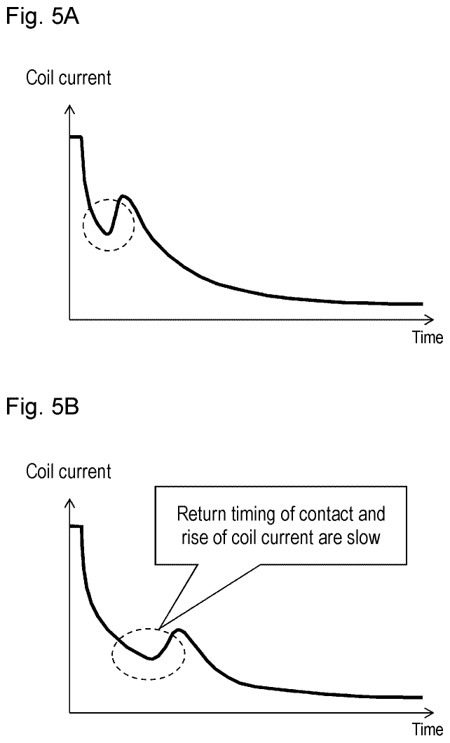

With reference to FIGS. 5A and 5B, a case will be described where the current waveform of the electric current flowing through the coil 21 when the contact 22 of the relay 20 is opened is acquired as the state of the relay 20. In the graphs in FIGS. 5A and 5B, the vertical axis represents the coil current, and the horizontal axis represents time. As described with reference to FIG. 4, when the switch for flowing the electric current to the coil 21 is turned off, the coil current decreases, and when the iron piece 25 is separated from the coil 21, the coil current once rises and then decreases.

FIG. 5A illustrates a current waveform of the coil current in a case where the timing at which the contact 22 returns to the open state is normal. FIG. 5B illustrates a current waveform of the coil current in a case where the timing at which the contact 22 returns to the open state is delayed. In FIG. 5B, the return timing of the contact 22 is slow, and the rise of the coil current is also slow.

The delay in the return timing of the contact 22 is possibly caused by an abnormality of the instrument 30 connected to the relay 20. For example, in a case where a short circuit occurs in the secondary-side circuit, the motor is locked, or the like, there are cases where the contact 22 is melted or welded due to overcurrent and the return of the contact 22 is delayed.

The abnormality detector 13 can predict or detect an abnormality of the instrument 30 by monitoring the current waveform of the coil current at the time when the contact 22 returns to the open state. The abnormality detector 13 can predict that the abnormality of the instrument 30 occurs, for example, in a case where the return timing of the contact 22 (the time when the coil current first becomes the minimum value) or the time until the coil current rises to the maximum value after the return is slower than the normal time.

The abnormality detection device 10 may predict or detect the abnormality of the instrument 30 by using the detection model 121 obtained by performing learning, as input data, the current waveform of the coil current at the time when the contact 22 returns to the opened state. In a case where the return timing of the contact 22 or the time until the coil current rises to the maximum value after the return is slower than the normal time, the abnormality detector 13 can detect the abnormality of the instrument 30 by inputting the current waveform of the coil current to the detection model 121.

According to the above embodiment, the abnormality detection device 10 can acquire the state of the relay 20 from the primary-side circuit of the relay 20 and predict or detect the abnormality of the instrument 30. Even if a monitoring sensor or the like is not attached to the instrument 30 to be monitored, the abnormality detection device 10 can indirectly monitor the instrument 30 connected to the secondary side by using the information acquired on the primary side of the relay 20.

Note that, in the above embodiment, the state of the relay 20 has been described by using the examples such as the information indicating the wear amount of the contact of the relay, the information indicating the distance between the coil and the iron piece at the time when the contact of the relay is closed, and the electric current waveform of the current flowing through the coil at the time when the contact of the relay is opened, but the state of the relay is not limited thereto. The state of the relay 20 only needs to be information that can indirectly predict or detect a failure of the instrument 30 connected to a circuit separated from the primary-side circuit of the relay 20.

Furthermore, the detection model 121 may be a model obtained by learning, as input data, at least one of temperature and humidity at the time when the state of the relay 20 is further acquired. The timing of opening and closing the contact 22 sometimes changes due to the influence of temperature or humidity. For this reason, the detection model 121 can detect the abnormality of the instrument 30 more accurately by learning at least one of the temperature and the humidity in addition to the state of the relay 20.

### <Others>

The above embodiment merely exemplarily describes a configuration example of the present invention. The present invention is not limited to the specific forms described above, and various modifications can be made within the scope of the technical idea.

Note that, in the above embodiment, the abnormality detection device 10 can also detect an abnormality of the instrument 30 by analyzing a voltage waveform (voltage value) instead of the current waveform (current value). A current value can be converted into a voltage value by using an appropriate shunt resistor, and measuring the current value is equivalent to measuring the voltage value. Therefore, as the state of the relay, the abnormality detection device 10 can detect the abnormality of the instrument 30 on the basis of the voltage waveform of the voltage applied to the coil at the time when the contact of the relay is opened.

### <Supplementary Note 1>

An abnormality detection device (10) including:
an acquisition unit (11) configured to acquire a state of a relay (20) that is connected to an instrument (30) to be monitored and controls opening and closing of a circuit to which the instrument (30) is connected;
a detector (13) configured to detect an abnormality of the instrument (30) on the basis of the state of the relay (20) or a change in the state of the relay (20); and
a notifying unit (14) configured to notify a user of the abnormality of the instrument (30) detected by the detector (13).

<Supplementary Note 2>

An abnormality detection method including:
an acquisition step of causing a computer to acquire a state of a relay (20) that is connected to an instrument (30) to be monitored and controls opening and closing of a circuit to which the instrument (30) is connected;
a detection step of causing the computer to detect an abnormality of the instrument (30) on the basis of the state of the relay (20) or a change in the state of the relay (20); and
a notification step of causing the computer to notify a user of the abnormality of the instrument (30) detected in the detection step.

### DESCRIPTION OF SYMBOLS

10 abnormality detection device
11 relay state acquisition unit
12 storage
121 detection model
13 abnormality detector
14 notifying unit
20 relay
21 coil
22 contact
22a movable contact
22b fixed contact
23 input-side terminal
24 output-side terminal
25 iron piece
30 instrument

1. An abnormality detection device comprising:
an acquisition unit configured to acquire a state of a relay that is connected to an instrument to be monitored and controls opening and closing of a circuit to which the instrument is connected;
a detector configured to detect an abnormality of the instrument on a basis of the state of the relay or a change in the state of the relay; and
a notifying unit configured to notify a user of an abnormality detected by the detector.

2. The abnormality detection device according to claim 1, wherein the detector detects an abnormality of the instrument by inputting the state of the relay or a change in the state of the relay acquired by the acquisition unit to a detection model, the detection model being subjected to machine learning using the state of the relay or the change in the state of the relay as input data and using an abnormality of the instrument related to the state of the relay or the change in the state of the relay as output data.

3. The abnormality detection device according to claim 2, wherein the detection model is a learned model obtained by performing machine learning using, as input data, a change amount of an index indicating a wear amount of a contact of the relay per unit time or per predetermined number of opening and closing times.

4. The abnormality detection device according to claim 2, wherein the detection model is a learned model obtained by performing machine learning using, as input data, time series data indicating a change in an index indicating a wear amount of a contact of the relay for a number of opening and closing times or a use time of the contact of the relay.

5. The abnormality detection device according to claim 2, wherein the detection model is a learned model obtained by further performing machine learning using, as the output data, a period until a failure occurs in the instrument.

6. The abnormality detection device according to claim 2, wherein the detection model is a learned model obtained by performing machine learning using an abnormality of the relay as the output data.

7. The abnormality detection device according to claim 1, wherein the state of the relay includes at least one of information indicating a wear amount of a contact of the relay, information indicating a distance between a coil and an iron piece at a time when the contact of the relay is closed, a current waveform of an electric current flowing through the coil at a time when the contact of the relay is opened, and a voltage waveform of a voltage applied to the coil at a time when the contact of the relay is opened.

8. The abnormality detection device according to claim 1, wherein the detector detects an abnormality of the relay on a basis of the state of the relay or a change in the state of the relay.

9. An abnormality detection method comprising:
an acquisition step of causing a computer to acquire a state of a relay that is connected to an instrument to be monitored and controls opening and closing of a circuit to which the instrument is connected;
a detection step of causing the computer to detect an abnormality of the instrument on a basis of the state of the relay or a change in the state of the relay; and
a notification step of causing the computer to notify a user of the abnormality detected in the detection step.

10. A non-transitory computer readable medium storing a program causing a computer to execute each step of an abnormality detection method comprising:
an acquisition step of causing a computer to acquire a state of a relay that is connected to an instrument to be monitored and controls opening and closing of a circuit to which the instrument is connected;
a detection step of causing the computer to detect an abnormality of the instrument on a basis of the state of the relay or a change in the state of the relay; and
a notification step of causing the computer to notify a user of the abnormality detected in the detection step.
